(19) United States
(12) Patent Application Publication
(10) Pub. No.: US 2026/0040836 A1
(43) Pub. Date: Feb. 5, 2026

(54) ELECTROCHEMICAL MEMORY CELL

(71) Applicant: SK hynix Inc., Icheon-si (KR)

(72) Inventors: Pil Hoon JUNG, Icheon-si (KR); Won Tae KOO, Icheon-si (KR)

(21) Appl. No.: 19/005,591

(22) Filed: Dec. 30, 2024

(30) Foreign Application Priority Data
Jul. 30, 2024 (KR) 10-2024-0101012

(51) Int. Cl. H10N 70/20; H10B 63/00; H10N 70/00

(52) U.S. Cl. CPC H10N 70/253; H10B 63/80; H10N 70/063; H10N 70/245

(57) ABSTRACT

An electrochemical memory cell may include a channel layer formed between a source and a drain, an electrolyte layer formed on an upper surface of the channel layer, and an ion storage layer formed on an upper surface of the electrolyte layer. The channel layer may have an uneven portion including a plurality of nano-patterns disposed on a surface of the channel layer to contact the electrolyte layer.

### CROSS-REFERENCE TO RELATED APPLICATION

The present application claims priority under 35 U.S.C. § 119(a) to Korean application number 10-2024-0101012, filed on Jul. 30, 2024, in the Korean Intellectual Property Office, which is incorporated herein by reference in its entirety.

### BACKGROUND

### 1. Technical Field

Example embodiments relate to a semiconductor integrated circuit device, and more specifically to an electrochemical memory cell.

### 2. Related Art

A next generation of computing devices is evolving toward an emerging memory configured to simultaneously compute and store data.

A typical emerging memory device may be an analog-compute in memory (A-CiM) device, which has a processor in the memory. The A-CiM device may use energy-efficient resistive memory cells as memory cells to reduce energy consumption due to frequent data transfers between the processor and a memory.

Currently, among resistive memory cells, an electrochemical random access memory (ECRAM) cell may be gaining prominence because of their precise ion transfer characteristics and resistance update characteristics that depend on the polarity of the applied voltage.

These electrochemical memory cells may need to satisfy high on/off ratio, high-speed operation characteristics, and low power consumption.

### SUMMARY

Example embodiments provide an electrochemical memory cell capable of achieving high resistance contrast, low power operation and high speed operation characteristics.

According to example embodiments, there may be provided an electrochemical memory cell. The electrochemical memory cell may include a channel layer, an electrolyte layer and an ion storage layer. The channel layer may be disposed between a source and a drain. The electrolyte layer may be disposed on an upper surface of the channel layer. The ion storage layer may be disposed on an upper surface of the electrolyte layer. The channel layer may include an uneven portion including a plurality of nano-patterns. The uneven portion may be disposed on an entire surface of the channel layer configured to contact to the electrolyte layer.

In example embodiments, the plurality of nano-patterns may include a nano-ring having holes having a diameter of several to tens of nanometers. The nano-rings have an outer diameter and an inner diameter in a cross section, and the outer diameter and the inner diameter are each several to tens of nanometers.

In example embodiments, the plurality of nano-patterns have a uniform width and may be regularly arranged with a uniform gap or pitch.

In example embodiments, the channel layer may include a center region and an edge region.

In example embodiments, a density of the plurality of nano-patterns disposed in the center region of the channel layer and a density of the plurality of nano-patterns disposed the edge region of the channel layer may be different from each other.

Alternatively, a size of the plurality of nano-patterns disposed in the center region of the channel layer may be different from a size of the plurality of nano-patterns disposed in the edge region of the channel layer.

According to example embodiments, there may be provided an electrochemical memory cell. The electrochemical memory cell may include a channel layer, an electrolyte layer, an ion storage layer and a gate. The channel layer may be located between a source and a drain. A voltage applied to the source and the drain. The electrolyte layer may be disposed on an upper surface of the channel layer. The ion storage layer may be disposed on an upper surface of the electrolyte layer. The gate may be disposed on an upper surface of the ion storage layer. The gate may receive a gate voltage to induce the ion storage layer into an electrochemical reaction. In this case, an entire junction surface of the channel layer and the electrolyte layer may have a plurality of uneven portions.

In example embodiments, the channel layer may include a plurality of the uneven portions. The uneven portions may include a plurality of nano-rings arranged on a surface of the channel layer configured to make contact with the electrolyte layer.

According to example embodiments, the channel layer in contact with the electrolyte layer of the electrochemical memory cell may be formed with the uneven portion including the plurality of nano-patterns throughout the entire surface of the channel layer. By the uneven portion, a contact area of the channel layer and the electrolyte layer may be increased, thereby increasing an ion exchange area of the memory operating ions.

As the ion exchange area of the memory operating ions may be increased, a large amount of ions may be exchanged in a shorter amount time, thereby improving operating voltage characteristics of the electrochemical memory cell, i.e., high conductance and fast conductance change. Accordingly, low power operation and high operating speed of an A-CiM device implementing the electrochemical memory cells of the disclosed embodiments may be advantageous.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a cross-sectional view illustrating an electrochemical memory cell in accordance with embodiments of the disclosure;

FIGS. 2A to 2C are perspective views illustrating a channel layer in accordance with embodiments of the disclosure;

FIG. 3 is a perspective view illustrating a channel layer in accordance with embodiments of the disclosure;

FIGS. 4A to 4C are perspective views illustrating a channel layer having an uneven portion in accordance with embodiments of the disclosure;

FIG. 5 is a flow chart illustrating a method of manufacturing an electrochemical memory cell in accordance with an embodiment of the disclosure;

FIGS. 6A to 6H are cross-sectional views illustrating a method of forming an uneven portion having a plurality of nano-rings in accordance with an embodiment of the disclosure;

FIGS. 7A to 7G are cross-sectional views illustrating a method of forming nano-rings in accordance with an embodiment of the disclosure;

FIGS. 8A and 8B are cross-sectional views illustrating a method of forming nano-rings in accordance with an embodiment of the disclosure;

FIG. 9A is a cross-sectional view illustrating a set program operation of an electrochemical memory cell in accordance with embodiments of the disclosure;

FIG. 9B is an enlarged perspective view of a portion “A” in FIG. 9A;

FIG. 10A is a cross-sectional view illustrating an operation for a reset program of an electrochemical memory cell in accordance with example embodiments of the disclosure;

FIG. 10B is an enlarged perspective view of a portion “A” of FIG. 10A;

FIG. 11 is a cross-sectional view illustrating a read operation of an electrochemical memory cell in accordance with example embodiments of the disclosure;

FIG. 12 is a graph illustrating impedance characteristics of an electrochemical memory cell in accordance with example embodiments of the disclosure;

FIG. 13 is a graph illustrating a conductance (G) of an electrochemical memory cell in accordance with example embodiments of the disclosure; and

FIG. 14 is a graph illustrating an amount of change in conductance (ΔG) of a memory cell in accordance with example embodiments of the disclosure.

### DETAILED DESCRIPTION

The advantages and features of the present disclosure, and methods of achieving them, will become apparent upon reference to embodiments described in detail with reference to the accompanying drawings. The disclosure, however, is not limited to the embodiments disclosed herein, but will be embodied in many different forms, and these embodiments are provided merely to make the disclosure of the disclosure complete, and to give those of ordinary skill in the technical field to which the disclosure belongs a complete idea of the scope of the disclosure. The dimensions and relative sizes of the layers and regions in the drawings may be exaggerated for clarity of description. Throughout the specification, like reference numerals refer to like components.

An electrochemical memory cell of an example embodiment may be applied to a memory cell of a resistive memory device, as well as to an A-CiM device, such as for example a neuromorphic memory device.

The electrochemical memory cell of an example embodiment will have operational characteristics that result from increasing a contact area with an electrolyte layer, which may be configured to exchange memory operating ions that determine data levels, and from the channel layer configured to store data.

For example, a contact area with the electrolyte layer and the channel layer may be larger than the layout area of the electrolyte layer. In order to increase the layout area to account for the larger contact area, the contact area of the electrolyte layer and the channel layer may have an uneven portion. The uneven portion may have a patterned structure having a plurality of patterns with a width in nanometers.

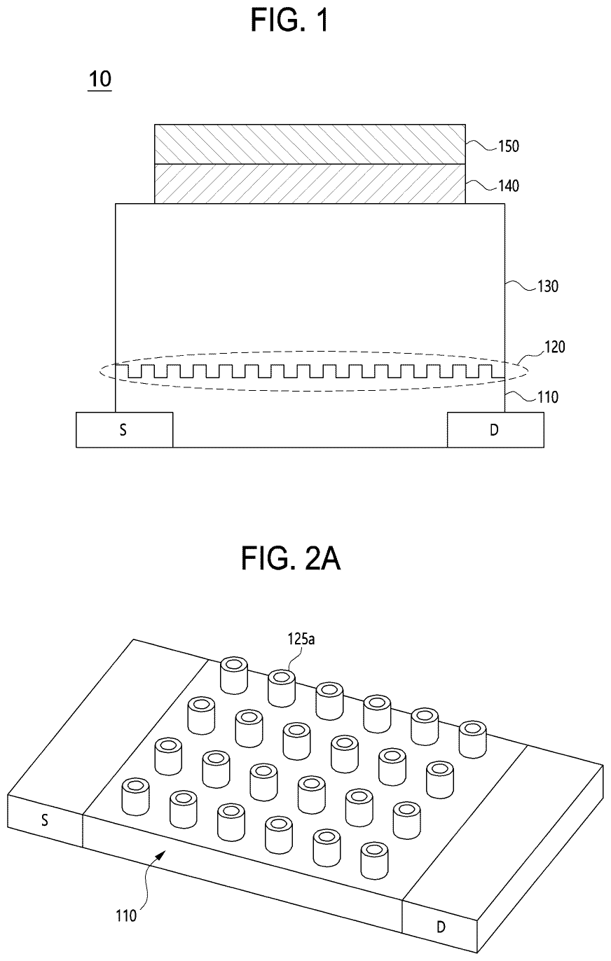

FIG. 1 is a cross-sectional view illustrating an electrochemical memory cell in accordance with embodiments of the disclosure.

Referring to FIG. 1, an electrochemical memory cell 10 of example embodiments may include a channel layer 110, an electrolyte layer 130 and an ion storage layer 140.

The channel layer 110 may be positioned between a source S and a drain D. The source S and drain D may be, for example, a conductive pattern. The channel layer 110 may be formed between the source S and the drain D such that an electrochemical ionization may occur in the channel layer 110 in response to a voltage applied to the source S and the drain D. The channel layer 110 may switch between a low resistive state (LRS) and a high resistive state (HRS) depending on concentrations of ions for memory operations in the channel layer 110. The ions will be described in more detail below. Accordingly, the channel layer 110 may be operated as a memory layer of the electrochemical memory cell 10.

The channel layer 110, the source S and the drain D may be formed over a substrate (not shown) such as a semiconductor substrate. Although not shown, the semiconductor substrate may include a silicon substrate, an SOI substrate, or a compound semiconductor substrate, but embodiments are not limited to these materials.

The electrolyte layer 130 may be positioned between the ion storage layer 140 and the channel layer 110. The electrolyte layer 130 may include an electrolyte material of liquid or solid composition. The electrolyte layer 130 may transfer ions or block ions. In example embodiments, the electrolyte layer 130 may include a high dielectric film.

The ion storage layer 140 may include a conductive material including the ions for the memory operations. The ion storage layer 140 may receive a voltage for performing one of the memory operations (hereinafter, operating voltage). The ion storage layer 140 generates ions for memory operations depending on a state of the operating voltage.

In example embodiments, the ion storage layer 140 may be operated as a gate of the electrochemical memory cell 10. The ion storage layer 140 may include ions for a memory operation.

A gate 150 may be formed on an upper surface of the ion storage layer 140 to receive a gate voltage. The gate 150 may include a metal component. The gate 150 may generate ions for a memory operation together with the ion storage layer 140.

In example embodiments, the gate may be omitted. If the gate is omitted, then the ion storage layer 140 may replace the gate.

The ions for the electrochemical memory cell 10 may include oxygen vacancies, hydrogen ions (H⁺), or lithium ions (Li⁺), but are not limited to these examples. The operation of the electrochemical memory cell 10 may vary depending on the type of ions.

In example embodiments, when oxygen vacancies (Vo) and oxygen ions (O²⁻) are used as the ions for a memory operation, the channel layer 110 may include at least one of WOₙ, PCMO (Pr_{0.7}CaMnO_{0.33}) and TiO₂. The electrolyte layer 130 may include at least one of HfOₓ, ZrO_{y} and a high dielectric material, such as yttria-stabilized zirconia (YSZ). The ion storage layer 140 may include at least one of metal oxide materials, such as ZrOₓ, TiO₂₋ₓ, and MoO_{y} materials.

When hydrogen ions (H⁺) are used as the ions for a memory operation, the channel layer 110 may include PEDOT:PSS/PEI, α-MoO3, NdNiO3, WO₃, or 2D Mxene materials, the electrolyte layer 130 may include liquid or organic electrolyte materials such as proton exchange membranes (PEMs), Nafion membranes and phosphosilicate glass (PSG), and the ion storage layer 140 may include PEDOT:PSS, Pd, or Si.

When lithium ions (Li⁺) are used as ions for a memory operation, the channel layer 110 may include WO₃, Liₓ₋₁CO₂ or graphene, the electrolyte layer 130 may include LiPON or Li₃PO₄, and the ion storage layer 140 may include Si or LiₓTiO₂.

A junction surface between the channel layer 110 and the electrolyte layer 130 of the example embodiments may have a plurality of uneven portions. The plurality of uneven portions may be obtained by forming an uneven portion 120 on an entire surface of the channel layer 110.

The uneven portion 120 may include a plurality of patterns (hereinafter, nano-patterns) having a width of several to tens of nanometers, such as about 0.1 nm about 90 nm. The nano-patterns of the uneven portion 120 may be regularly or evenly arranged with a uniform gap and a uniform width, as will be described in more detail below.

Alternatively, the nano-patterns of the uneven portion 120 may be irregularly arranged.

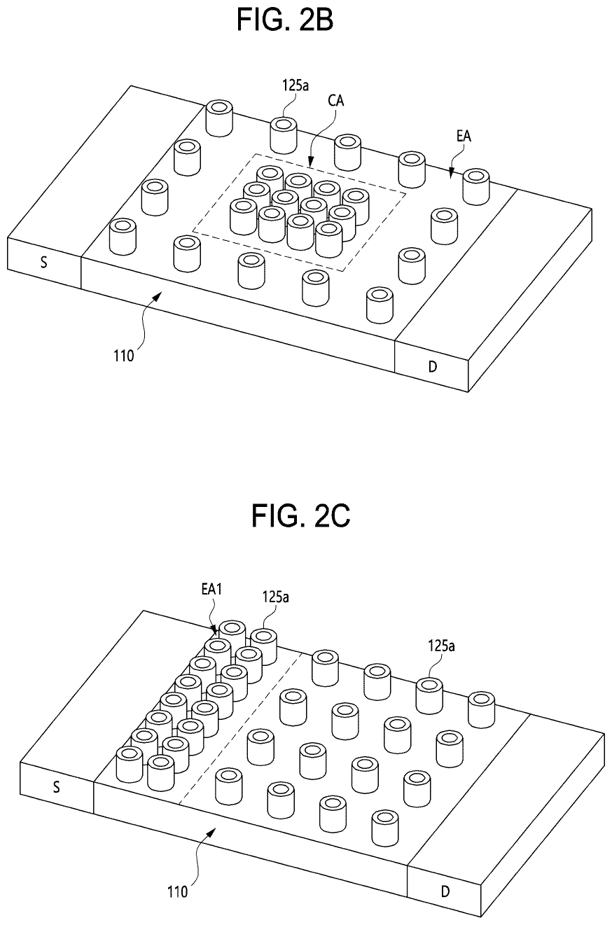

FIGS. 2A to 2C are perspective views illustrating a channel layer in accordance with embodiments of the disclosure.

Referring to FIGS. 1 and 2A, nano-patterns 125a may be arranged uniformly in a channel layer 110 between the source S and the drain D. Accordingly, ion exchanges may be regularly distributed over an entire area of the channel layer 110.

Alternatively, as shown in FIG. 1 and FIG. 2B, the nano-patterns 125a may be formed at a relatively higher density in a center region CA compared with an edge region EA of the channel layer 110. As a larger number of nano-patterns 125a may be disposed in the center region CA of the channel layer 110, which overlaps with ion sources gate 150 and ion storage layer 140, so more ions may be transferred to the channel layer 110 in the center region CA compared with the edge region.

Alternatively, the density of the nano-patterns 125a in at least some of an edge region EA1 of the channel layer 110, as shown in FIG. 2C, may be greater than in other regions. As a result, generation of a conduction path in the channel layer 110 is facilitated by disposing a relatively large number of nano-patterns 125a in the edge region EA1 of the channel layer 110 adjacent to the source S.

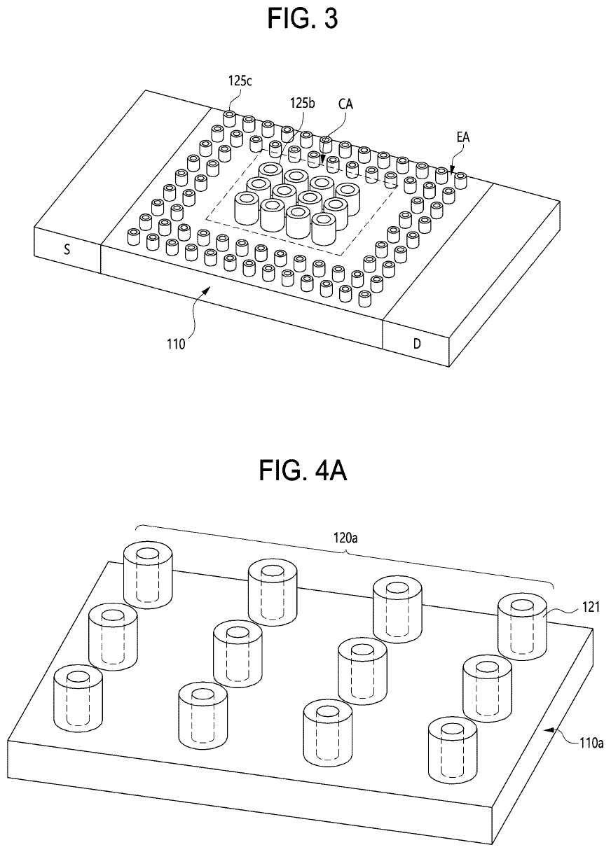

FIG. 3 is a perspective view illustrating a channel layer in accordance with embodiments of the disclosure.

Referring to FIG. 3, a channel layer 110 may include a plurality of nano-patterns 125b and 125c, which differ in size. For example, the size of a nano-pattern 125b disposed in a center region CA of the channel layer 110 may be different from the size of a nano-pattern 125c disposed in an edge region EA of the channel layer 110. In example embodiments, the sizes of nano-patterns may include a height and a width.

In example embodiments, the nano-patterns 125b disposed in the center region CA of the channel layer 110 may be larger than the nano-patterns 125c disposed in the edge region EA of the channel layer 110. However, without being limited hereto, it is possible to form the nano-patterns 125c disposed in the edge region of the channel layer 110 to be larger than the nano-patterns 125b disposed in the center region of the channel layer 110.

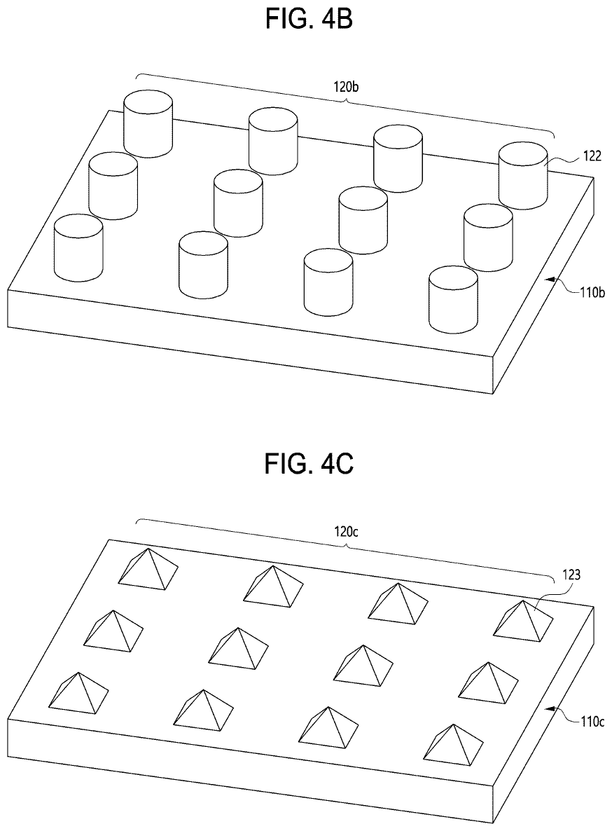

FIGS. 4A to 4C are perspective views illustrating a channel layer having an uneven portion in accordance with embodiments of the disclosure.

Referring to FIG. 4A, a channel layer 110a may include an uneven portion 120a including a plurality of nano-rings patterns 121. A nano-ring pattern 121 may have a cylindrical shape with an outer diameter and an inner diameter of several to tens of nanometers. The outer diameter, the inner diameter and the height of the nano-rings patterns 121 may be changed to account for operational characteristics of an electrochemical memory cell 10.

Alternatively, referring to FIG. 4B, a channel layer 110b may include an uneven portion 120b including a plurality of nano-pillar patterns 122. For example, a nano-pillar pattern 122 may have a width of several to tens of nanometers. Similarly, a diameter and a height of a nano-pillar pattern 122 may be changed to account for the operational characteristics of the electrochemical memory cell 10.

Further, referring to FIG. 4C, a channel layer 110c may include an uneven portion 120c including a plurality of nano pyramids 123. For example, the lengths and widths of each nano pyramid 123 may gradually decrease from a lower portion common to an upper surface of channel layer 110c to a top portion of the nano pyramid. The lower width (e.g., maximum width) of the nano pyramids 123 may have a width of a few to tens of nanometers. The height of the nano pyramids 123 may be designed to account for the operational characteristics of the electrochemical memory cell 10.

Since the channel layer 110 can include uneven portions 120a, 120b, or 120c corresponding respectively to nano-rings patterns 121, nano-pillar patterns 122, or nano pyramids 123, the contact area between the channel layer 110 and the electrolyte layer 130 increases. As a result, the area over which ions are exchanged (hereinafter, ion exchange area) between the channel layer 110 and the electrolyte layer 130 is larger compared to an ion exchange area without uneven portions. By increasing the ion exchange area, the operating speed of an electrochemical memory cell 10 may be increased and low voltage operations are possible.

In example embodiments, when comparing electrochemical memory cells 10 with the same number and distribution of the nano-rings patterns 121, the nano-pillar patterns 122 and the nano pyramids 123 formed respectively on the channel layers 110, the electrochemical memory cell 10 with nano-rings patterns 121 on the channel layer 110 may have the largest surface area and therefore the largest ion exchange area.

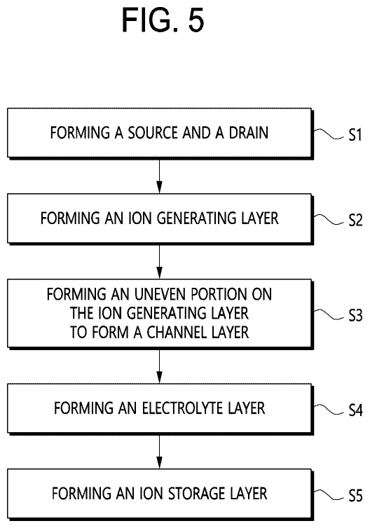

FIG. 5 is a flow chart illustrating a method of manufacturing an electrochemical memory cell in accordance with an embodiment of the disclosure.

Referring to FIGS. 1 and 5, a source S and a drain D may be formed over a semiconductor substrate (not shown) or a base layer (not show) including at least one layer (S1). For example, step 1 (S1) includes providing the semiconductor substrate or the base layer. A conductive layer may be formed over an upper surface of the substrate, and an insulation layer may be formed between the conductive layer and the semiconductor substrate (or the base layer). The conductive layer may include a low resistive metal layer that includes, for example, a Pt material, but embodiments are not limited to this example. The conductive layer may be patterned by a lithographic process to form a source S and drain D spaced apart by a set distance. The set distance may correspond to a channel length in a layout of an electrochemical memory cell 10.

Next, an ion generating layer (not shown) is formed over the semiconductor substrate on which the source S and drain D are formed (S2). The ion generating layer may include a region that may later form a channel layer 110. When a voltage is applied to the gate 150, the ion generating layer may generate ions for performing a memory operation. The ion generating layer may include various materials in accordance with type of the ions used in the memory operation.

An uneven portion 120 may be formed on a surface of the ion generating layer to form a channel layer 110 (S3). The uneven portion 120 may include a plurality of nano-rings patterns 121, a plurality of nano-pillar patterns 122, or a plurality of nano pyramids 123 each having the width of several to tens of nanometers, as described above.

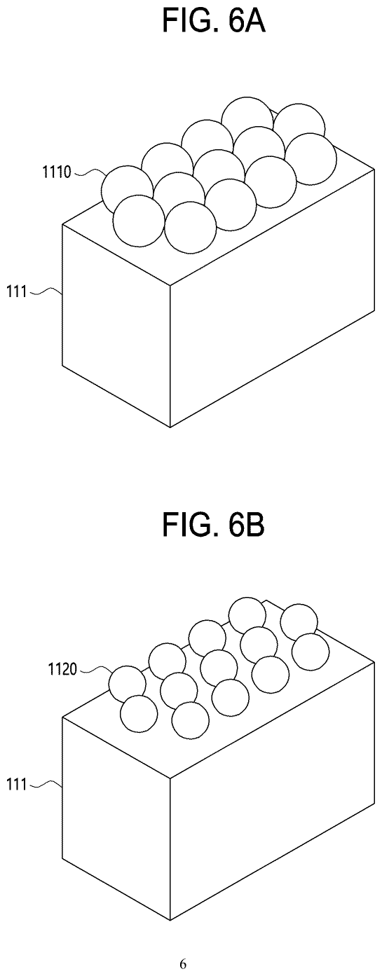

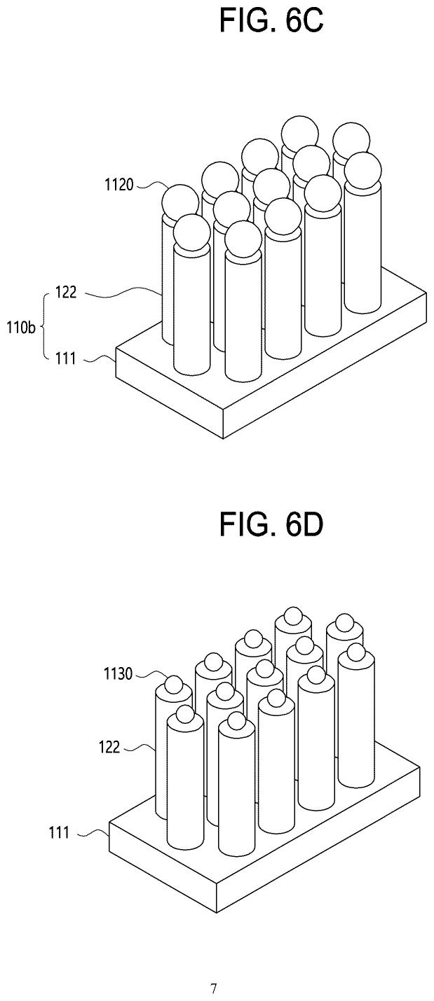

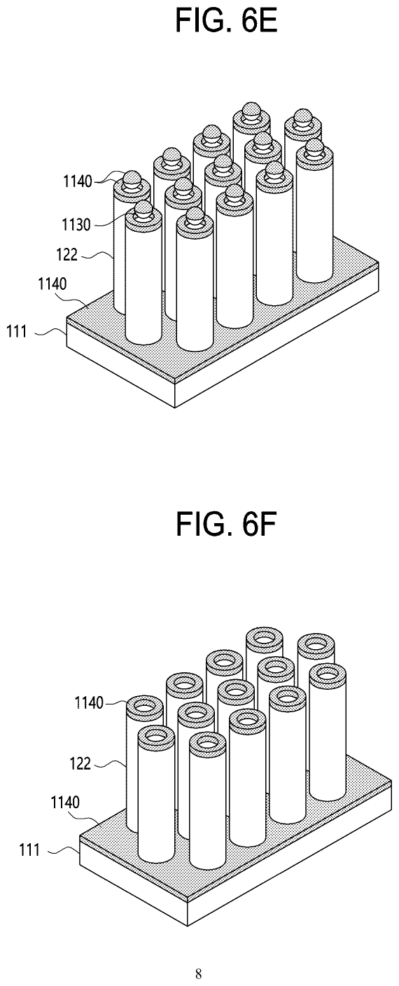

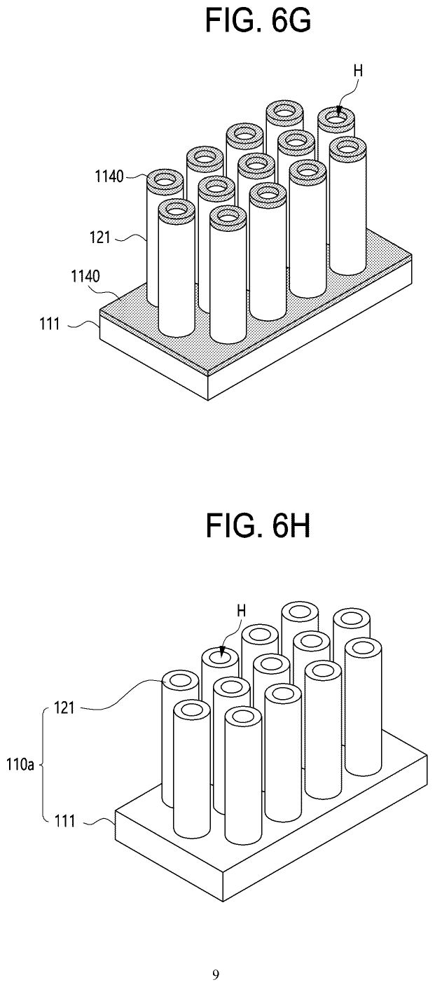

FIGS. 6A to 6H are cross-sectional views illustrating a method of forming an uneven portion having a plurality of nano-rings in accordance with an embodiment of the disclosure.

First, referring to FIG. 6A, a plurality of first annular structures 1110 may be formed on an upper surface of an ion generating layer 111. The plurality of first annular structures 1110 may be formed of a material having a different etch selectivity ratio compared with the ion generating layer 111. For example, the first annular structures 1110 may include at least one of, but not limited to, a polystyrene sphere, a carbon sphere, a hollow carbon sphere, an aerogel annular structure, a metal oxide annular structure and a hollow metal oxide annular structure.

Referring to FIG. 6B, a shrinking process may be performed on the first annular structures 1110 to result in a plurality of second annular structures 1120 formed on the upper surface of the ion generating layer 111. The first annular structures may have larger diameters than the second annular structures, which have diameters reduced to several to tens of nanometers. For example, the shrinking process may include a thermal treatment process, but embodiments are not limited to this example and various processes may be applied.

Next, referring to FIG. 6C, the ion generating layer 111 may be etched to a set thickness, using the plurality of second annular structures 1120 as a mask. The set thickness may be less than the thickness of the ion generating layer 111. Accordingly, a plurality of nano-pillar patterns 122 may be formed on the upper surface of the ion generating layer 111. In other embodiments, referring to FIG. 4B, if the plurality of second annular structures 1120 are removed, then a channel layer 110b including an uneven portion 120b with the plurality of nano-pillar patterns 122 may be formed.

Referring to FIG. 6D, through a shrinking process, a second annular structure 1120 may form a third annular structure 1130 on each of the nano-pillar patterns 122. For example, the second annular structures 1120 may be subjected to a shrinking process such that the third annular structures 1130 may be positioned respectively at the centers of upper surfaces of the nano-pillar patterns 122.

Then, referring to FIG. 6E, a sacrificial layer 1140 may be formed on an upper surface of the ion generating layer 111 in an anisotropic manner. Accordingly, the sacrificial layer 1140 may be formed on a surface substantially parallel to the upper surface of the ion generating layer 111, such as the upper surface of the ion generating layer 111, a surface of the third annular structure 1130, and the upper surface of a nano-pillar pattern 122 exposed by the third annular structure 1130. In example embodiments, the sacrificial layer 1140 may include a material having an etch selectivity ratio with the ion generating layer 111 and with the third annular structure 1130. For example, the sacrificial layer 1140 of example embodiments may include a nickel layer (Ni). Further, the sacrificial layer 1140 may be formed by an evaporation technique such that the sacrificial layer 1140 may be anisotropically formed. In this case, as the sacrificial layer 1140 is anisotropically formed, the sacrificial layer 1140 may be formed in an upper region of the third annular structure 1130, but the sacrificial layer 1140 not formed in a lower region of the third annular structure 1130. Accordingly, the lower region of the third annular structure 1130 may be exposed.

Next, the plurality of third annular structures 1130 may be selectively removed, as shown in FIG. 6F. An etchant may be introduced through the lower region of the exposed third annular structure 1130, such that the plurality of third annular structures 1130 may be selectively removed. As the plurality of third annular structures 1130 are removed, the center region of each of the plurality of nano-pillar patterns 122 without the sacrificial layer 1140 are exposed.

Referring to FIG. 6G, using the sacrificial layer 1140 as a mask, the center region of the exposed plurality of nano-pillar patterns 122 may be etched to form holes H in the nano-pillar patterns 122. The depth of the hole H may be the same as or different from a height of the nano-pillar patterns 122. The depth of the hole H may be selected in consideration of the operating characteristics of the electrochemical memory cell 10.

Next, referring to FIG. 6H, the remaining sacrificial layer 1140 may be removed to form a channel layer 110a having an uneven portion 120a comprising the plurality of nano-rings patterns 121 and an ion generating layer 111.

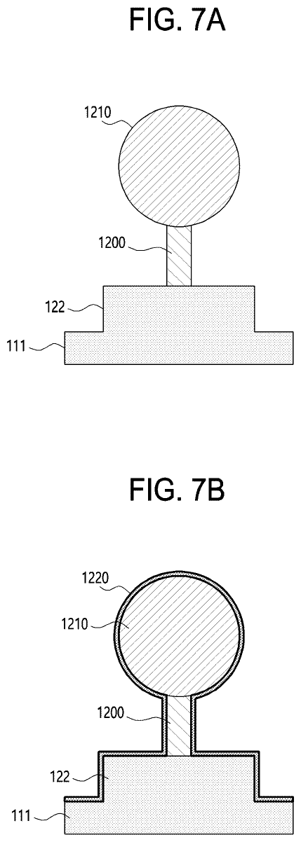

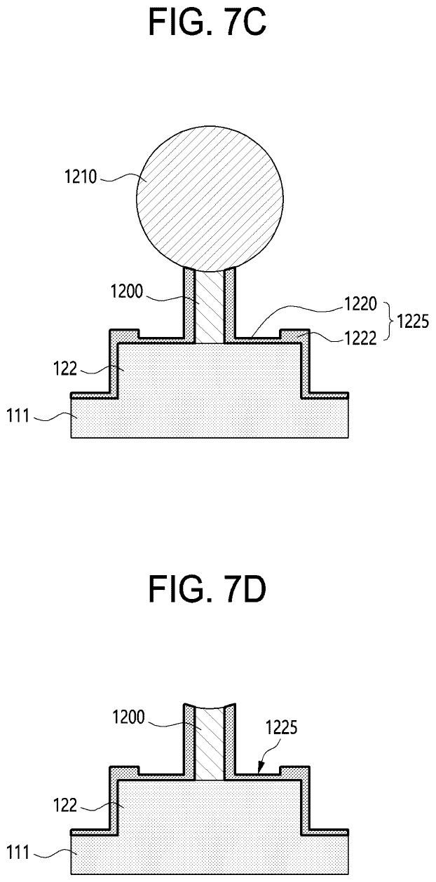

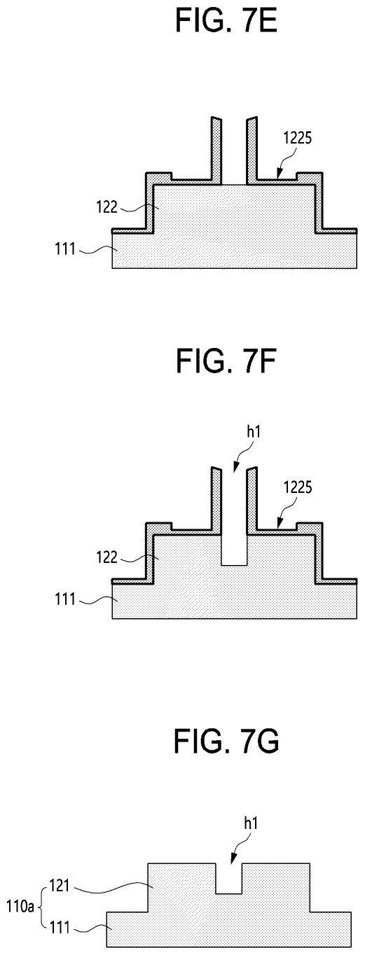

FIGS. 7A to 7G are cross-sectional views illustrating a method of forming nano-rings in accordance with an embodiment of the disclosure.

Referring to FIG. 7A, a polymer layer (not illustrated) and an annular structure 1210 may be sequentially formed on an ion generating layer 111. The annular structure 1210 may have different etch selectivity ratios with respect to the polymer layer and the ion generating layer 111.

Next, using the annular structure 1210 as a mask, the polymer layer and a portion of the ion generating layer 111 may be etched, to form a polymer pattern 1200. In the etching process, an etchant in which more of the polymer layer may be etched than the ion generating layer 111 may be used. Alternatively, etching the ion generating layer 111 and etching the polymer layer may be performed separately using different etchants.

When the portion of the ion generating layer 111 is patterned, using the annular structure 1210 as the mask, to have a diameter of a few to several nanometers, nano-pillar patterns 122 shown in FIGS. 7A and 4B may be patterned on the ion generating layer 111.

On the other hand, since the polymer layer may be etched at a faster etch rate than the ion generating layer 111, the polymer pattern 1200 may be formed to have a narrower width than the nano-pillar patterns 122.

Referring to FIG. 7B, a first sacrificial layer 1220 may be formed over the surfaces of the ion generating layer 111, the nano-pillar patterns 122, the polymer pattern 1200 and the annular structure 1210. The first sacrificial layer 1220, such as a nickel layer, may include a material having an etch selectivity for the ion generating layer 111, the polymer pattern 1200 and the annular structure 1210. For example, the nickel layer may be deposited by sputtering, but techniques are not limited thereto.

Then, as shown in FIG. 7C, the first sacrificial layer 1220 formed on the surface of the annular structure 1210 may be selectively removed. For example, the first sacrificial layer 1220 may be removed by a reactive ion etching process using a Cl₂ gas.

A reactive ion etching process may be a known anisotropic etching process. Therefore, in the process of removing the first sacrificial layer 1220 from the surface of the annular structure 1210, some of the first sacrificial layer 1220 located in a direction perpendicular to the upper surface of the ion generating layer 111 may be lost.

In example embodiments, a second sacrificial layer 1222 may be additionally formed on sidewalls of the polymer pattern 1200 and the nano-pillar patterns 122 to compensate for the loss of the first sacrificial layer 1220. The second sacrificial layer 1222 is not formed on the surface of the annular structure 1210. Because the second sacrificial layer 1222 may also be formed from the same nickel layer material as the first sacrificial layer 1220 and because the second sacrificial layer 1222 may be selectively formed only where the first sacrificial layer 1220 was lost in the previous etching process, a sacrificial layer 1225 including the first and second sacrificial layers 1220 and 1222 may have partially different thicknesses.

As shown in FIG. 7D, the exposed annular structure 1210 may be selectively removed. For example, when the annular structure 1210 may include a silicon oxide layer, the annular structure 1210 may be selectively removed using an HF solution.

Referring to FIG. 7E, the polymer pattern 1200 exposed by the sacrificial layer 1225 may be selectively removed. For example, the polymer pattern 1200 may be removed by an O₂ reactive ion etching process, but techniques are not limited thereto.

Then, referring to FIG. 7F, using the sacrificial layer 1225 as a mask, the exposed nano-pillar patterns 122 may be etched to a selected depth to form a hole h1 in the nano-pillar patterns 122. For example, the nano-pillar patterns 122 may be etched using a reactive ion etching process using a Cl₂ gas to form the hole h1.

Referring to FIG. 7G, the sacrificial layer 1225 may be removed to form a channel layer 110a including nano-rings patterns 121 and an ion generating layer 111.

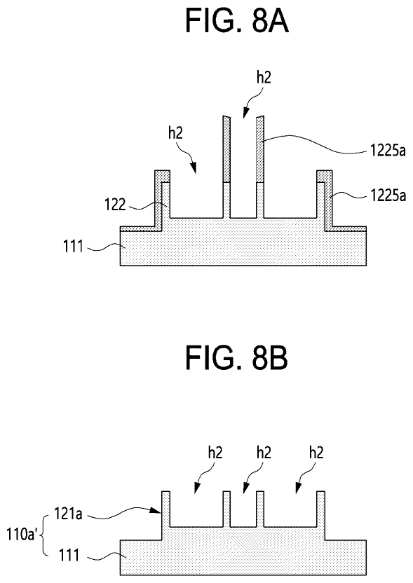

FIGS. 8A and 8B are cross-sectional views illustrating a method of forming nano-rings in accordance with an embodiment of the disclosure. This method assumes a structure identical to that shown in FIG. 7E as an initial starting point, and subsequent processes in the method will now be described below.

Referring to FIG. 8A, a sacrificial layer 1225 formed on an upper surface of the nano-pillar pattern 122 may be recessed to a predetermined thickness. Through the recess process, a width and a thickness of the sacrificial layer 1225 located common to the sidewall portion of the polymer pattern 1200 that was etched away, and a width and a thickness of the sacrificial layer 1225 located on the sidewall portion of the nano-pillar pattern 122, may be reduced. Further, a portion of the sacrificial layer 1225 having a relatively smaller thickness on the upper surface of the nano-pillar pattern 122 may be removed. Accordingly, a plurality of sacrificial nano-pillar patterns 1225a may remain on the upper surface of the nano-pillar pattern 122.

Thereafter, using the plurality of sacrificial nano-pillar patterns 1225a as a mask, the nano-pillar patterns 122 may be etched to a predetermined depth to form multiple holes h2 in the nano-pillar pattern 122.

Next, referring to FIG. 8B, the plurality of sacrificial nano-pillar patterns 1225a may be removed to form a channel layer 110a′ with nano-rings 121a having multiple holes h2 and an ion generating layer 111.

Although various methods of forming nano-rings have been described in the above embodiments, in addition to using annular structures, the uneven portion 120 having various shapes of nano-patterns may be formed using photolithography processes using cylindrical photoresist patterns (or hard mask patterns) and nano imprint processes.

Referring again to FIGS. 1 and 5, an electrolyte layer 130 may be formed on an upper surface of the channel layer 110 (S4). Since the electrolyte layer 130 may be formed to be in contact with the uneven portion 120, including the plurality of nano-patterns, the contact area between the electrolyte layer 130 and the channel layer 110 may be larger than the layout area of the channel layer 110.

Thereafter, the ion storage layer 140 may be formed on the upper surface of the electrolyte layer 130 (S5).

### Set Program Operation

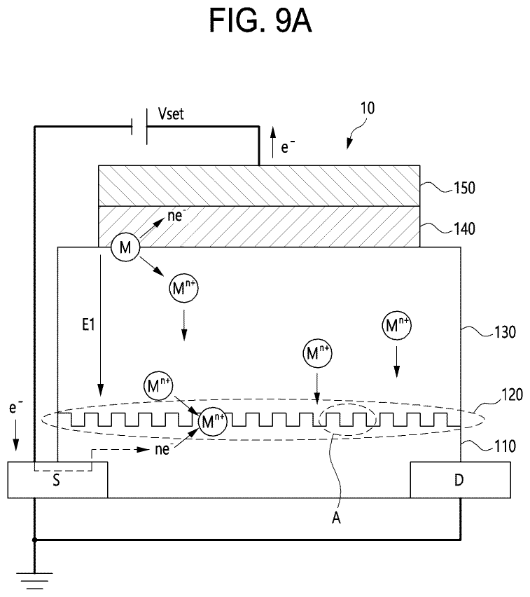

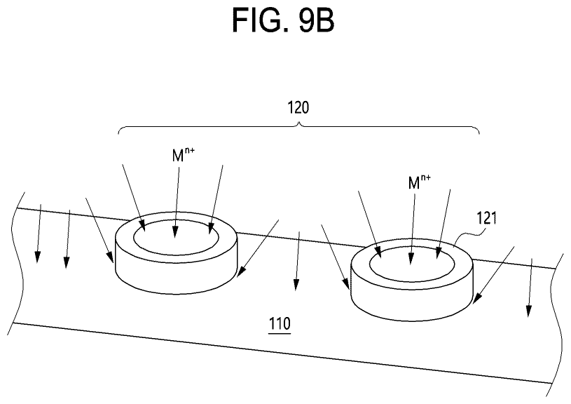

FIG. 9A is a cross-sectional view illustrating a set program operation of an electrochemical memory cell in accordance with embodiments of the disclosure. FIG. 9B is an enlarged perspective view of a portion “A” in FIG. 9A. The embodiments below assume the memory operation ions to be oxygen vacancies and oxygen ions, but other embodiments may use different ions.

Referring to FIG. 9A, in an electrochemical memory cell 10, a set voltage Vset having a positive level may be applied to an ion storage layer 140, and a ground voltage may be applied to a source S and drain D so that a channel layer 110 having an uneven portion 120 located between the source S and the drain D may also have a ground voltage level. Accordingly, a first electric field E1 may be generated in the direction of the channel layer 110 from the ion storage layer 140, and an electrolyte layer 130 may become an ion conductor in which ion migration occurs under the first electric field E1.

The set voltage Vset may be greater than a threshold voltage Vth of the electrochemical memory cell 10. The threshold voltage Vth may be a minimum voltage that induces an electrochemical reaction of the ion storage layer 140 and channel layer 110.

When the set voltage Vset is applied to the ion storage layer 140, compounds in the ion storage layer 140 may be ionized into cations (Mⁿ⁺) and anions (ne⁻), such as oxygen vacancies and oxygen ions.

Accordingly, the cations (Mⁿ⁺) generated in the ion storage layer 140 may be transferred to the channel layer 110 via the electrolyte layer 130. The cations (Mⁿ⁺) may react with the anions in the channel layer 110, thereby increasing the conductivity of the channel layer 110.

Referring to FIG. 9B, because a plurality of nano-rings patterns 121 may be formed on the surface of the channel layer 110, the cations (Mⁿ⁺) may be enter the channel layer 110 via a horizontal surface of the channel layer 110 as well as through the outer and inner surfaces of the plurality of nano-rings patterns 121.

That is, the contact area of the channel layer 110 and the electrolyte layer 130 may be increased by the plurality of nano-rings patterns 121 formed on the surface of the channel layer 110. A comparatively larger amount of the cations (Mⁿ⁺) may be provided to the channel layer 110 through the increased contact area. Accordingly, the ion bonding reaction in the channel layer 110 may proceed more quickly as the resistance of the channel layer 110 is lowered more rapidly.

Since the cations (Mⁿ⁺) in the ion storage layer 140, including a metal oxide layer with the mostly metal components, the increased concentration of cations (Mⁿ⁺) in the channel layer 110 may cause the resistance of the channel layer 110 to be lower than a reference resistance. Accordingly, the electrochemical memory cell 10 may have a low resistance state (LRS) resulting from the set program operation.

### Reset Program Operation

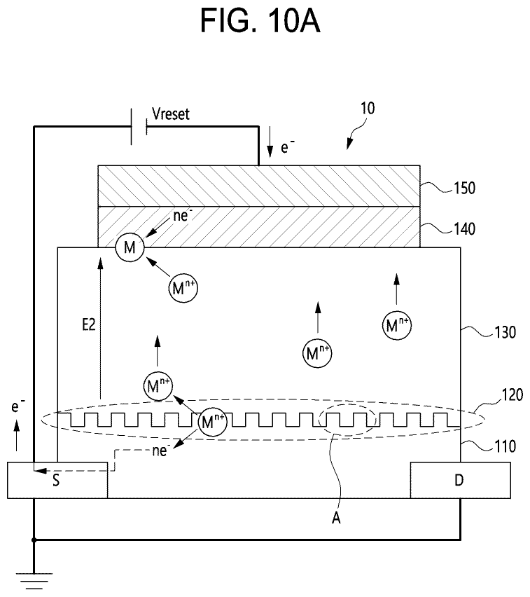

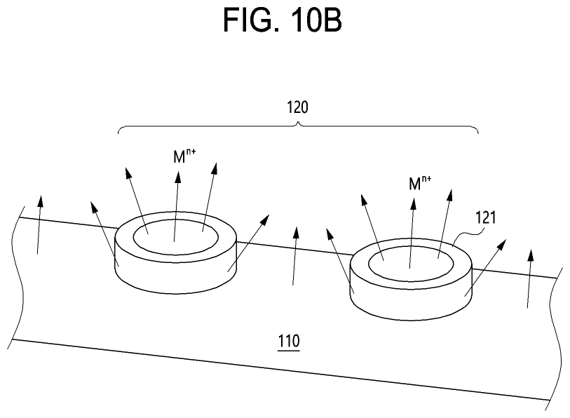

FIG. 10A is a cross-sectional view illustrating a reset program operation of an electrochemical memory cell in accordance with embodiments of the disclosure. FIG. 10B is an enlarged perspective view of a portion “A” in FIG. 10A.

Referring to FIG. 10A, in an electrochemical memory cell 10, a reset voltage Vreset may be applied to an ion storage layer 140, and a voltage greater than the reset voltage Vreset may be applied to a source S and drain D. For example, the reset voltage Vreset may have a voltage lower than a threshold voltage Vth of the electrochemical memory cell 10, such as a negative voltage level.

By applying the reset voltage Vreset, a second electric field E2 may be generated in a direction from a channel layer 110 toward the ion storage layer 140.

In addition, the channel layer 110, which may be provided with a positive voltage, and the ion storage layer 140, which may be provided with the reset voltage Vreset, may be subjected to an electrochemical reaction.

As the positive voltage may be applied to the channel layer 110, the anions (ne) in the channel layer 110, such as oxygen ions (O²⁻), may be increase. In addition, positive ions (Mⁿ⁺) in the channel layer 110 may be move toward the ion storage layer 140 along a direction of the second electric field E2.

As such, a concentration of oxygen ions (O²⁻) in the channel layer 110 may be increase, and the resistance of the channel layer 110 may become higher than the reference resistance. Accordingly, the electrochemical memory cell 10 enter a high resistive state (HLS).

Referring to FIG. 10B, positive ions (Mⁿ⁺) of the channel layer 110 may be discharged into the electrolyte layer 130 from the horizontal surface of the channel layer 110 and from a plurality of nano-rings patterns 121 formed on the surface of the channel layer 110. Ion exchange through the outer surface and the inner surface of the nano-rings patterns 121 increase the concentration of negative ions in the channel layer 110 at a rapid rate, thereby changing the resistance state of the electrochemical memory cell 10 at a rapid rate.

### Read Operation

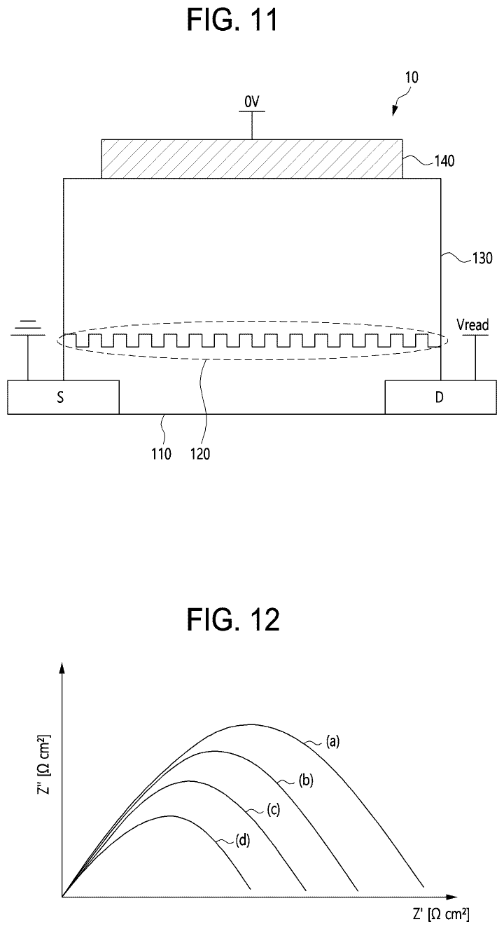

FIG. 11 is a cross-sectional view illustrating a read operation of an electrochemical memory cell in accordance with example embodiments of the disclosure.

Referring to FIG. 11, in order to read data stored in a channel layer 110 of an electrochemical memory cell 10, only the channel layer 110 between a drain D and the source S may be conducted.

In example embodiments, 0 V may be applied to an ion storage layer 140, a read voltage Vread may be applied to the drain D, and a ground voltage may be applied to the source S. The read voltage Vread may be a voltage level that does not result in varying the ion concentration in the channel layer 110.

Then, by measuring an output current of the drain D, the data state stored in the channel layer 110 may be read and it may be determined whether the resistance of the channel layer 110 may be above or below the reference resistance.

FIG. 12 is a graph illustrating impedance characteristics of an electrochemical memory cell in accordance with example embodiments of the disclosure. For reference, FIG. 12 is a graph of measured electrochemical impedance spectra (EIS) under the same voltage and same temperature conditions of electrochemical memory cells 10 with a channel layer (a) with a flat surface, a channel layer (b) including a plurality of nano pyramids 123 in FIG. 4C, a channel layer (c) including a plurality of nano-pillar patterns 122 in FIG. 4B, and a channel layer (d) including a plurality of nano-rings patterns 121 in FIG. 4A in accordance with example embodiments.

Referring to FIG. 12, with the number and the width of the nano pyramids 123, the nano-pillar patterns 122, and the nano-rings patterns 121 substantially the same, the contact area with the electrolyte layer increases in the order of the channel layer with the flat surface, the channel layer with the nano pyramids 123, the channel layer with the nano-pillar patterns 122 and the channel layer with the nano-rings patterns 121. On the other hand, a polarization resistance Z″ of electrochemical memory cells 10 may be characterized as decreasing as the contact area of the channel layer 110 and the electrolyte layer 130 is increasing.

Faster operation speeds correspond to smaller polarization resistance Z″ of the electrochemical memory cells 10. Therefore, electrochemical memory cells 10 with a channel layer (d) with a plurality of nano-rings patterns 121 formed in the channel layer 110 will exhibit the fastest operation characteristics corresponding to the lowest polarization resistance Z″.

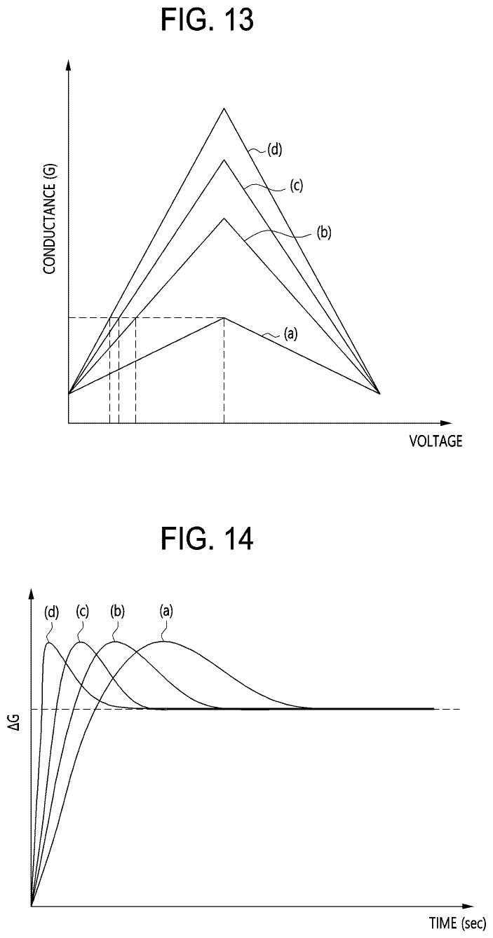

FIG. 13 is a graph illustrating a conductance G of an electrochemical memory cell in accordance with example embodiments of the disclosure. For reference, a curve (a) in FIG. 13 shows a conductance of an electrochemical memory cell having a flat channel layer, and a curve (b) shows a conductance of an electrochemical memory cell having a channel layer 110c including a plurality of nano pyramids 123 described with reference to FIG. 4C, a curve (c) represents a conductance of an electrochemical memory cell having a channel layer 110b including a plurality of nano pillars patterns 122 described with reference to FIG. 4B, and a curve (d) represents a conductance of an electrochemical memory cell having a channel layer 110a including a plurality of nano-rings patterns 121 described with reference to FIG. 4A.

Referring to FIG. 13, it is shown that as the contact area of the channel layer and the electrolyte layer increases, the conductance G of the electrochemical memory cell increases. A magnitude of the conductance G represents a set/reset contrast ratio (or on/off contrast ratio) of the electrochemical memory cell. As a result, when utilizing the channel layer 110a including the plurality of nano-rings patterns 121, such as in example embodiments, a high resistance contrast ratio may be obtained under a low voltage when compared to the electrochemical memory cell with a flat channel layer. Accordingly, the electrochemical memory cell of example embodiments may be operated at lower power compared to electrochemical memory cells without an uneven portion.

FIG. 14 is a graph illustrating an amount of change in conductance ΔG of a memory cell in accordance with example embodiments of the disclosure. A curve (a) in FIG. 14 shows a change in conductance of an electrochemical memory cell having a flat channel layer, and a curve (b) shows a change in conductance of an electrochemical memory cell having a channel layer 110c including a plurality of nano pyramids 123 described with reference to FIG. 4C, a curve (c) represents a change in conductance of an electrochemical memory cell having a channel layer 110b including a plurality of nano-pillar patterns 122 described with reference to FIG. 4B, and a curve (d) represents a change in conductance of an electrochemical memory cell having a channel layer 110a including a plurality of nano-rings patterns 121 described with reference to FIG. 4A.

Referring to FIG. 14, the amount of change in conductance ΔG indicates the time at which the change in conductance occurs, and shows that the amount of change in conductance ΔG may be ordered sequentially for the channel layer 110a having the plurality of nano-rings patterns 121, the channel layer 110b having the plurality of nano-pillar patterns 122, the channel layer 110c having the plurality of nano pyramids 123 and the flat channel layer.

Thus, it can be noted that the higher the contact area between the channel layer and the electrolyte layer, the higher the speed of operation.

According to the present disclosure, a channel layer of an electrochemical memory cell is formed to include a plurality of nano-patterns to increase the contact area between the channel layer and an electrolyte layer. Thus, an actual contact area between the channel layer and the electrolyte layer increases, thereby expanding the ion exchange area available for memory operations, which significantly improves operating characteristics.

As the ion exchange area for memory operating ions is increased, a larger amount of ions may be interchanged in a short period of time, thereby improving the operating voltage characteristics, range of channel conductance, and faster conductance change of the electrochemical memory cell. Accordingly, low power operation and high operating speed of A-CiM devices comprising the electrochemical memory cells of the present embodiment may be advantageous.

While the present disclosure has been described in detail with reference to preferred embodiments, the disclosure is not limited to the above embodiments, but is capable of many modifications by those having ordinary skill in the art within the scope of the technical ideas of the disclosure.

What is claimed is:

1. An electrochemical memory cell comprising:
a channel layer disposed between a source and a drain;
an electrolyte layer disposed on the channel layer; and
an ion storage layer disposed on the electrolyte layer,
wherein the channel layer comprises an uneven portion including a plurality of nano-patterns disposed on a surface of the channel layer.

2. The electrochemical memory cell of claim 1, wherein the plurality of nano-patterns comprises a plurality of nano-rings, each of the nano-rings having an outer diameter and an inner diameter in a cross section, and
wherein the outer diameter and the inner diameter are each several to tens of nanometers.

3. The electrochemical memory cell of claim 2, wherein the electrolyte layer is disposed to contact the outer diameter and the inner diameter of the plurality of nano-rings.

4. The electrochemical memory cell of claim 1, wherein each of the plurality of nano-patterns has a uniform width and the plurality of nano-patterns are spaced with a uniform gap.

5. The electrochemical memory cell of claim 1, wherein the channel layer comprises a center region and an edge region, and a density of the plurality of nano-patterns disposed in the center region of the channel layer is different from a density of the plurality of nano-patterns disposed in the edge region of the channel layer.

6. The electrochemical memory cell of claim 1, wherein the channel layer comprises a center region and an edge region, and a size of the plurality of nano-patterns disposed in the center region of the channel layer is different from a size of the plurality of nano-patterns disposed in the edge region of the channel layer.

7. The electrochemical memory cell of claim 1, wherein the ion storage layer comprises a material that generates ions for memory operations through an electrochemical reaction in response to a gate voltage applied to the ion storage layer.

8. The electrochemical memory cell of claim 1, wherein the channel layer comprises a material that generates ions for a memory operation through an electrochemical reaction with a source voltage applied to the source and a drain voltage applied to the drain.

9. The electrochemical memory cell of claim 1, wherein the electrolyte layer comprises a material that exchanges ions between the ion storage layer and the channel layer in a memory operation, based on a direction of an electric field generated between the ion storage layer and the channel layer.

10. The electrochemical memory cell of claim 1, wherein the plurality of nano-patterns comprises a plurality of nano-rings, each of the nano-rings having a hole therein, and
wherein each hole has a diameter of several to tens of nanometers.

11. The electrochemical memory cell of claim 1, wherein each of the plurality of nano-patterns has a nano pyramid structure, and a lower width of the nano pyramid structure is a few to tens of nanometers.

12. An electrochemical memory cell comprising:
a channel layer located between a source and a drain, wherein a source voltage is applied to the source and a drain voltage is applied to the drain;
an electrolyte layer formed on the channel layer;
an ion storage layer formed on the electrolyte layer; and
a gate formed on the ion storage layer, the gate receiving a gate voltage to induce an electrochemical reaction in the ion storage layer,
wherein a contact surface between the channel layer and the electrolyte layer has a plurality of nano-patterns.

13. The electrochemical memory cell of claim 12, wherein the plurality of nano-patterns comprises a plurality of nano-rings, each of the nano-rings in a cross section having an outer diameter, an inner diameter, a height and an internal depth measured from an upper surface of the nano-ring,
wherein the outer diameter and the inner diameter are each several to tens of nanometers, and
wherein at least one portion of the electrolyte layer has a pillar structure disposed to contact an inner surface of the plurality of nano rings common to the inner diameter.

14. The electrochemical memory cell of claim 13, wherein the internal depth is equal to a height of the pillar structure.

15. The electrochemical memory cell of claim 13, wherein the internal depth is less than a height of the pillar structure.

16. The electrochemical memory cell of claim 12, wherein each of the plurality of nano-patterns has a uniform width and the plurality of nano-patterns are spaced with a uniform pitch as part of a surface of the channel layer that contacts the electrolyte layer.

17. The electrochemical memory cell of claim 12, wherein the channel layer comprises a center region and an edge region, and
wherein a density of the plurality of nano-patterns disposed in the center region of the channel layer is different from a density of the plurality of nano-patterns disposed in the edge region of the channel layer.

18. The electrochemical memory cell of claim 12, wherein the channel layer comprises a center region and an edge region, and
wherein a size of the plurality of nano-patterns disposed in the center region of the channel layer is different from a size of the plurality of nano-patterns disposed in the edge region of the channel layer.

19. The electrochemical memory cell of claim 14, wherein the internal depth is less than a height of the nano-ring.
